(19) United States
(12) Patent Application Publication
(10) Pub. No.: US 2026/0305126 A1
(43) Pub. Date: Oct. 1, 2026

(54) DISPLAY DEVICE AND METHOD FOR MANUFACTURING DISPLAY DEVICE

(71) Applicant: Sharp Display Technology Corporation, Kameyama City, Mie (JP)

(72) Inventor: Kenichiroh TSUCHIDA, Kameyama City, Mie (JP)

(21) Appl. No.: 19/477,646

(22) PCT Filed: Apr. 25, 2023
(86) PCT No.: PCT/JP2023/016199

§ 371 Date: Oct. 22, 2025

(51) Int. Cl. H10K 59/80; H10K 102/00

(52) U.S. Cl. CPC H10K 59/872; H10K 2102/311

(57) ABSTRACT

A display device includes a display panel including a plurality of layers having flexibility, and at least one locking portion located at a part of an outer edge of the display panel. The display panel includes an inward bending portion allowing an upper surface to be curved inward, and an outward bending portion allowing the upper surface to be curved outward. The locking portion includes a first opposing portion opposing an upper surface at an outer edge of the outward bending portion, and a second opposing portion opposing a lower surface at the outer edge of the outward bending portion.

### TECHNICAL FIELD

The disclosure relates to a display device including a display panel having flexibility and a method for manufacturing the display device.

### BACKGROUND ART

A technique is known in which a display panel included in a display device is made flexible to allow bending and extending of the display device. Here, in a case in which the display panel includes a plurality of layers, stress may occur between an inner layer and an outer layer at a curved portion due to a curve of the display panel, leading to peeling of the plurality of layers of the display panel. PTL 1: JP 2022-536882 T discloses a technique for reducing the above-described peeling by providing an opening in a support plate of the display panel.

### SUMMARY

### Technical Problem

According to the technique described in PTL 1: JP 2022-536882 T, it is difficult to relieve the stress itself that leads to peeling of the plurality of layers of the display panel, making it difficult to efficiently reduce the peeling.

### Solution to Problem

A display device according to an aspect of the disclosure includes a display panel layered with a plurality of layers having flexibility and at least one locking portion located at a part of an outer edge of the display panel, in which the display panel includes an upper surface and a lower surface, the display panel further including an inward bending portion allowing the upper surface to be curved inward and an outward bending portion allowing the upper surface to be curved outward, the locking portion including a first opposing portion opposing the upper surface at an outer edge of the outward bending portion, a second opposing portion opposing the lower surface at the outer edge of the outward bending portion, and a connection portion connecting the first opposing portion and the second opposing portion.

A manufacturing method for a display device according to an aspect of the disclosure is a manufacturing method for a display device including a display panel including a plurality of layers having flexibility, the display panel including an upper surface and a lower surface, the display panel further including an inward bending portion allowing the upper surface to be curved inward and an outward bending portion allowing the upper surface to be curved outward, the method including forming the display panel by layering the plurality of layers, and forming a locking portion including a first opposing portion opposing the upper surface at an outer edge of the outward bending portion, a second opposing portion opposing the lower surface at the outer edge of the outward bending portion, and a connection portion connecting the first opposing portion and the second opposing portion.

### Advantageous Effects of Disclosure

Stress that occurs in each layer of the display panel is more effectively relieved, and peeling of each layer of the display panel is reduced.

### BRIEF DESCRIPTION OF DRAWINGS

FIG. 1 is a schematic view of a display device in an extended state according to a first embodiment.

FIG. 2 is an enlarged perspective view of a locking portion and a display panel in the vicinity of the locking portion in a case in which the display device according to the first embodiment is in the extended state.

FIG. 3 is a schematic side view of the display device according to the first embodiment in a bent state.

FIG. 4 is an enlarged perspective view of the locking portion and the display panel in the vicinity of the locking portion in a case in which the display device according to the first embodiment is in the bent state.

FIG. 5 is a schematic view of an inward bending portion of the display panel in a case in which the display device according to the first embodiment is in the extended state and the bent state, respectively.

FIG. 6 is a schematic view of a display device according to a second embodiment in an extended state.

FIG. 7 is a schematic view of a mesh layer and a protrusion according to the second embodiment.

FIG. 8 is an enlarged perspective view of the protrusion and a display panel in the vicinity of the protrusion in a case in which the display device according to the second embodiment is in a bent state.

FIG. 9 is a schematic perspective view of a mesh material layer according to the second embodiment.

### DESCRIPTION OF EMBODIMENTS

### First Embodiment

Embodiments of the disclosure will be described below with reference to the drawings. In each drawing, the same components are denoted by the same reference numerals and signs, and description thereof is omitted.

### Display Device

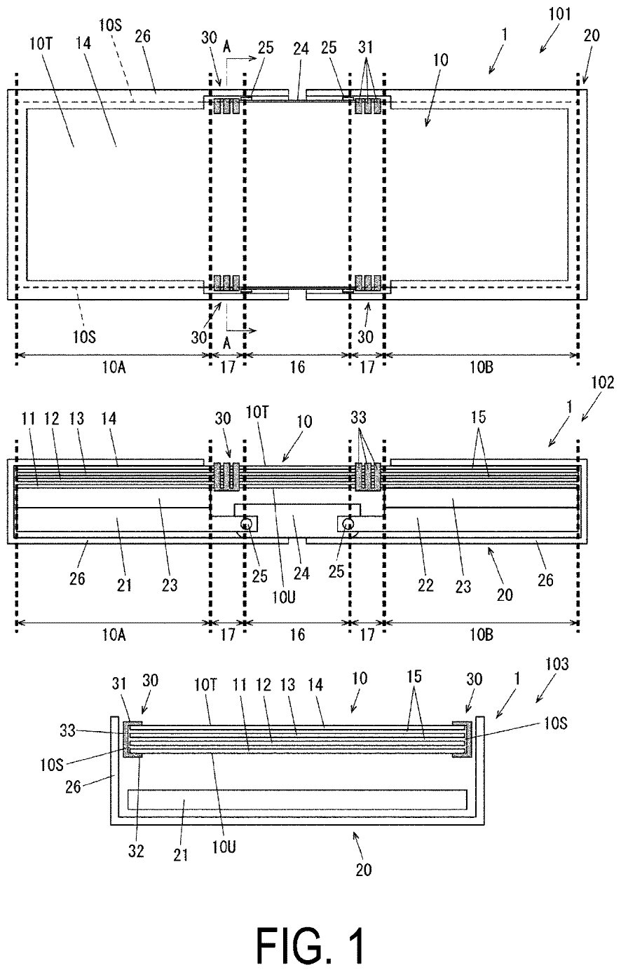

FIG. 1 is a schematic view of a display device 1 according to the present embodiment. In particular, FIG. 1 illustrates a schematic plan view 101 of the display device 1, a schematic side view 102 of the display device 1, and a schematic cross-sectional view 103 of the display device 1. In particular, the schematic plan view 101 is a plan view of the display device 1 as viewed from a side of an upper surface 10T including a display surface of a display panel 10 to be described later. In addition, the schematic side view 102 is a side view illustrating a side surface along a longitudinal direction of the display device 1. Further, the schematic cross-sectional view 103 is a cross-sectional view taken along line A-A in the schematic plan view 101, in other words, a cross-sectional view in a cross section orthogonal to the upper surface 10T of the display panel 10 and passing through a locking portion 30 to be described later. Note that in the schematic side view 102, a portion of a bezel 26, to be described later, which is located on the near side toward the paper surface is omitted in the illustration, in order to illustrate components of the display device 1 more clearly. FIG. 1 illustrates a case in which the display device 1 is in an extended state. The case in which the display device 1 is in the extended state is a state in which the display surface of the display panel 10 to be described later is located substantially on the same plane.

The display device 1 is a device that can be used as a display of, for example, a television, a smartphone, or the like. The display device 1 includes the display panel 10, a housing portion 20, and the locking portion 30. In particular, the display device 1 according to the present embodiment is a foldable device in which the display panel 10 has flexibility and can be folded inward at the display surface of the display panel 10.

### Display Panel

The display panel 10 is a display panel in which a plurality of layers including a light-emitting element layer 11, a touch panel film 12, a polarizing film 13, and a window film 14 are layered in order from the lower side of the display device 1. In the present embodiment, the display panel 10 includes a lower surface of the light-emitting element layer 11 as a lower surface 10U and an upper surface of the window film 14 as the upper surface 10T. Further, a side surface 10S of the display panel 10 includes a side surface of each of the layers of the display panel 10.

The display panel 10 further includes a bonding layer 15 between each of the plurality of layers described above. The bonding layer 15 includes an adhesive material having optical transparency and bonds each of the layers of the display panel 10 to one another, from the light-emitting element layer 11 to the window film 14. In particular, the display panel 10 includes at least one bonding layer 15 between at least two layers for bonding the two layers to each other. The thickness of each of the bonding layers 15 is, for example, from 15 μm to 75 μm. The side surface 10S of the display panel 10 includes side surfaces of each of the bonding layers 15.

The light-emitting element layer 11 includes a plurality of subpixels each including a light-emitting element. Each of the light-emitting elements emits light toward the upper surface 10T by being individually driven, for example, by a driver (not illustrated) included in the display device 1. The light-emitting element layer 11 may include, as the light-emitting element, an organic EL element (OLED element) including an organic fluorescent material or the like as a luminescent material. Alternatively, the light-emitting element layer 11 may include, as the light-emitting element, a quantum dot light-emitting element (QLED element) including luminescent quantum dots (nanoparticle semiconductors) as a luminescent material. The thickness of the light-emitting element layer 11 may be, for example, 30 μm.

The touch panel film 12 includes, for example, a plurality of electrode pairs arranged in a plan view. The display device 1 may measure a change in electric capacitance between each pair of electrodes of the touch panel film 12 to detect contact of a human body or the like on a display surface of the display device 1. However, the touch panel film 12 is not limited thereto, and may include various known touch panel films that detect contact of a human body or the like on the display surface of the display panel 10. The thickness of the touch panel film 12 may be, for example, 45 μm.

The polarizing film 13 is, for example, a film that transmits only light having a specific polarization. The polarizing film 13, for example, reduces light that enters the display surface of the display panel 10 from outside the display device 1 and is reflected by the electrode or the like of the light-emitting element in the light-emitting element layer 11 from reaching a viewer of the display device 1. The polarizing film 13 may include, for example, a linear polarizer or a circular polarizer, and may further include a half-wavelength plate or a quarter-wavelength plate. The thickness of the polarizing film 13 may be, for example, 30 μm.

The window film 14 is a film including, for example, a transparent resin, and having a function of protecting the display surface of the display panel 10. The thickness of the window film 14 may be, for example, 60 μm.

The total thickness of the display panel 10 may be, for example, from 300 μm to 400 μm.

Each of the layers of the display panel 10 has flexibility. In particular, in the present embodiment, the display panel 10 includes an inward bending portion 16 and an outward bending portion 17, which will be described later, at a central side in a longitudinal direction of the display device 1. The inward bending portion 16 allows the upper surface 10T of the display panel 10 to be curved inward. The outward bending portion 17 allows the lower surface 10U of the display panel 10 to be curved inward, and, in other words, allows the upper surface 10T to be curved outward.

In a case in which the display device 1 is in the extended state, the upper surface 10T of the display panel 10, including the inward bending portion 16 and the outward bending portion 17, is located substantially on the same plane. For example, in a case in which the display device 1 is in the extended state, each of the layers of the display panel 10 has a substantially flat plate shape. Note that “substantially on the same plane” does not necessarily mean being positioned exactly on the same plane, and allows, for example, positional differences due to manufacturing errors or the like. The term “substantially flat plate shape” does not necessarily mean a completely flat plate, and allows, for example, variations in shape and film thickness due to manufacturing errors and the like.

### Housing Portion

The housing portion 20 includes a first housing 21, a second housing 22 different from the first housing 21, two adhesive tapes 23, a hinge portion 24, two pins 25, and the bezel 26.

Each of the first housing 21 and the second housing 22 is a base material at least more rigid than the display panel 10, bonded to the lower surface 10U of the display panel 10, and having a function of supporting the display panel 10. The first housing 21 and the second housing 22 may include various materials usable as base materials, such as glass substrates and film substrates. In a case in which the display device 1 is in the extended state, upper surfaces of the first housing 21 and the second housing 22 are located substantially on the same plane.

Each of the adhesive tapes 23 bonds the display panel 10 to each of the first housing 21 and the second housing 22. The adhesive tape 23 is not limited to an adhesive material having optical transparency, and may include various adhesive materials. The thickness of the adhesive tape 23 may be, for example, 50 μm.

The first housing 21 is bonded to, for example, a first portion 10A located on one side in a longitudinal direction of the display panel 10 via the adhesive tape 23. In addition, the second housing 22 is bonded to a second portion 10B, which is located on the opposite side of the first portion 10A in the longitudinal direction of the display panel 10, via the adhesive tape 23. Therefore, in a plan view of the display panel 10, the first portion 10A overlaps a bonding position with the first housing 21, and the second portion 10B overlaps a bonding position with the second housing 22.

Note that, in the present embodiment, the display panel 10 includes the inward bending portion 16 and the outward bending portion 17 between the first portion 10A and the second portion 10B. In particular, the outward bending portions 17 are located between the first portion 10A and the inward bending portion 16 and between the second portion 10B and the inward bending portion 16, respectively.

The hinge portion 24 rotatably connects the first housing 21 and the second housing 22 to each other via two pins 25, which will be described later. The hinge portion 24 is formed, for example, on each of the side surfaces 10S along the longitudinal direction of the display device 1, and between the first housing 21 and the second housing 22.

Each of the pins 25 is a bar-shaped member substantially parallel to a short-hand direction of the display device 1. One pin 25 penetrates the first housing 21 and the hinge portion 24, and restrains the first housing 21 and the hinge portion 24 so as to be rotatable with respect to each other. The other pin 25 penetrates the second housing 22 and the hinge portion 24, and restrains the second housing 22 and the hinge portion 24 so as to be rotatable with respect to each other.

The bezel 26 is an exterior covering that forms a part of an outer surface of the display device 1, and covers lower surfaces and side surfaces of the first housing 21 and the second housing 22, and also covers an outer edge of the upper surface 10T and a part of the side surfaces 10S of the display panel 10. In particular, the bezel 26 functions as the exterior covering that conceals a frame portion including outer edges of the display panel 10, the first housing 21, and the second housing 22. The bezel 26 may be divided between the first housing 21 and the second housing 22 or may individually cover the first housing 21 and the second housing 22 in order to facilitate bending of the display device 1 described later.

The housing portion 20 may include, for example, a member that supports between the first portion 10A and the second portion 10B of the display panel 10, between the first housing 21 and the second housing 22. The housing portion 20 may include, for example, a plate spring that is in contact with the display panel 10 while curving in a convex shape toward the display panel 10 between the first housing 21 and the second housing 22.

### Locking Portion

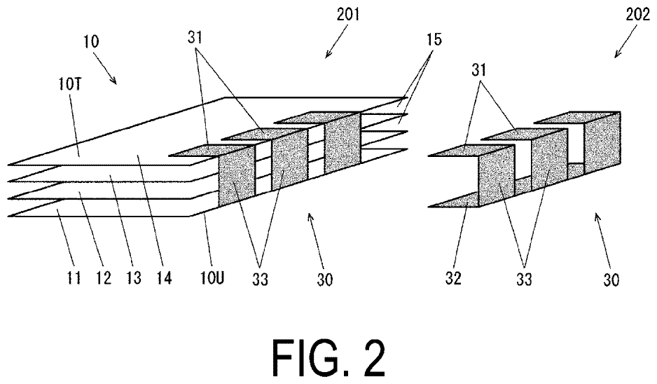

Subsequently, the locking portion 30 included in the display device 1 will be described in more detail with reference to FIG. 2 in addition to FIG. 1. FIG. 2 is an enlarged perspective view of the locking portion 30 and the display panel 10 in the vicinity of the locking portion 30 when the display device 1 is in the extended state. In particular, FIG. 2 illustrates an enlarged perspective view 201 illustrating the locking portion 30 and the display panel 10 located in the vicinity of the locking portion 30, and an enlarged perspective view 202 illustrating only the locking portion 30 extracted therefrom.

The locking portion 30 includes a plurality of first opposing portions 31, a single second opposing portion 32, and a plurality of connection portions 33. Each of the first opposing portions 31, the second opposing portion 32, and the connection portions 33 is a plate-shaped member that includes, for example, a metal material or the like and has a predetermined rigidity. Each of the connection portions 33 connects each of the first opposing portions 31 and the second opposing portion 32. Each of the first opposing portions 31 and the second opposing portion 32 faces each other, and a planar direction of each of the connection portions 33 and each of the first opposing portions 31 and a planar direction of each of the connection portions 33 and the second opposing portion 32 are substantially orthogonal. Each of the first opposing portions 31 and the second opposing portion 32 is formed at each end portion of each of the connection portions 33 in a thickness direction of the display device 1. When the display device 1 is in the extended state, the plurality of first opposing portions 31 and the second opposing portion 32 are in a substantially flat plate shape.

The length of each of the first opposing portions 31 and the second opposing portion 32 in the short-hand direction of the display device 1 may be, for example, from 1 mm to 2 mm. The length of the second opposing portion 32 in the longitudinal direction of the display device 1 may be, for example, from 5 mm to 10 mm. The length of each connection portion 33 in the thickness direction of the display device 1, in other words, a distance between each of the first opposing portions 31 and the second opposing portion 32 may be substantially the same as the total thickness of the display panel 10, for example.

The locking portion 30 is located at a part of the outer edges of the display panel 10. The first opposing portions 31 oppose the upper surface 10T of the display panel 10, and the second opposing portion 32 opposes the lower surface 10U of the display panel 10. In addition, the connection portions 33 oppose the side surface 10S of the display panel 10. In particular, the outer edges of the display panel 10 are inserted between the first opposing portions 31 and the second opposing portion 32 to a position where the side surface 10S of the display panel 10 comes into contact with the connection portions 33, so that the locking portion 30 is fixed to the display panel 10.

The locking portion 30 according to the present embodiment is located at an outer edge of the outward bending portion 17, which will be described later, among the outer edges of the display panel 10. The first opposing portions 31 oppose the upper surface 10T at the outer edge of the outward bending portion 17, the second opposing portion 32 opposes the lower surface 10U at the outer edge of the outward bending portion 17, and the connection portions 33 oppose the side surface 10S at the outward bending portion 17. In a case in which the display panel 10 includes a plurality of outward bending portions 17, the locking portions 30 may be located at an outer edge of each of the plurality of outward bending portions 17.

### Bending of Display Device

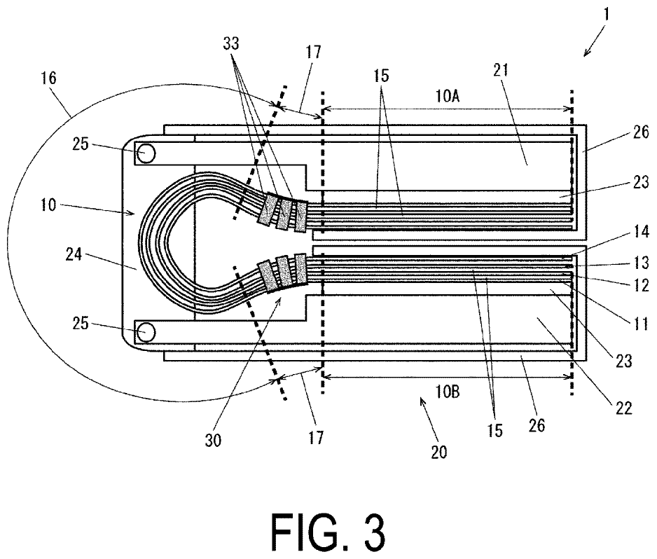

Bending of the display device 1 according to the present embodiment will be described with reference to FIG. 3. FIG. 3 is a schematic side view of the display device 1 in a bent state. In particular, FIG. 3 illustrates, among the side surfaces of the display device 1, a side surface that is the same side surface as that of the display device 1 illustrated in the schematic side view 102. In addition, in FIG. 3, a portion of the bezel 26 which is located on the near side toward the paper surface is omitted in the illustration, in order to illustrate components of the display device 1 more clearly.

The display device 1 is brought into the bent state from the extended state by the first housing 21 and the second housing 22 rotating around the respective pins 25 until the upper surfaces of the first housing 21 and the second housing 22 face each other. The display device 1 may take the extended state, in which display is performed substantially on the same plane, and the bent state, in which the length in the longitudinal direction is reduced, by the housing portion 20. Therefore, the display device 1 can increase an area of the display surface during display, while reducing a dimension of the display device 1 during non-display. In the bent state, an upper surface of the bezel 26 overlapping the first portion 10A and the upper surface of the bezel 26 overlapping the second portion 10B may be in contact with each other.

In a case in which the display device 1 is in the bent state, the display panel 10 is curved between the first portion 10A and the second portion 10B. Here, the display panel 10 of the display device 1 in the bent state is curved with the upper surface 10T on the inner side at the inward bending portion 16, and is curved with the upper surface 10T on the outer side at the outward bending portion 17. Therefore, the display panel 10 curves in a teardrop shape between the first portion 10A and the second portion 10B. In a case in which the housing portion 20 includes a support portion for the display panel 10 including the above-described plate spring between the first housing 21 and the second housing 22, the support portion may be deformed by being pressed by the curved display panel 10. Thus, the support portion may support the display panel 10 in a case in which the display device 1 is in either the extended state or the bent state.

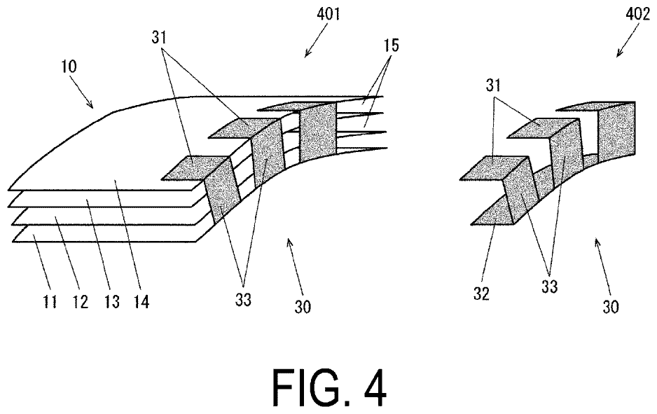

The locking portion 30 in a case in which the display device 1 is in the bent state will be described with reference to FIG. 4. FIG. 4 is an enlarged perspective view of the locking portion 30 and the display panel 10 in the vicinity of the locking portion 30 in a case in which the display device 1 is in the bent state. In particular, FIG. 4 illustrates an enlarged perspective view 401 illustrating the locking portion 30 and the display panel 10 located in the vicinity of the locking portion 30, and an enlarged perspective view 402 illustrating only the locking portion 30 extracted therefrom.

The locking portion 30 is deformed by curving the second opposing portion 32 inward in response to a curve of the display panel 10 at the outward bending portion 17. In particular, the second opposing portion 32 of the locking portion 30 is curved along a curve of the light-emitting element layer 11 at the outward bending portion 17. Further, two adjacent first opposing portions 31 and two adjacent connection portions 33 move to positions where a distance between the two adjacent first opposing portions 31 and a distance between the two adjacent connection portions 33 increase in accordance with a curve of the outward bending portion 17.

Since the locking portion 30 is curved outward on sides of the first opposing portions 31, tensile stress occurs on the sides of the first opposing portions 31 of the locking portion 30. In the present embodiment, the locking portion 30 can reduce tensile stress that occurs in each of the first opposing portions 31 and each of the connection portions 33 during the above deformation, compared with a case in which only a single first opposing portion 31 and a single connection portion 33 are provided, and can deform while more closely following the curve of the display panel 10. Further, since each of the first opposing portions 31 is connected to the single second opposing portion 32 via each of the connection portions 33, the locking portion 30 allows each of the first opposing portions 31 and each of the connection portions 33 to appropriately and easily move in response to a curve of the second opposing portion 32. Thus, the locking portion 30 including the plurality of first opposing portions 31, the plurality of connection portions 33, and the single second opposing portion 32 deforms while more closely following the curve of the outward bending portion 17, and reduces damage to the display panel 10.

Note that, as illustrated in the schematic side view 102, the locking portion 30 is located in a periphery of the hinge portion 24 in the side view of the display device 1. In addition, as illustrated in the schematic plan view 101, the bezel 26 covers a periphery of the locking portion 30 in the display panel 10. Thus, the locking portion 30 reduces interference with the hinge portion 24 or the bezel 26 during a change between the extended state and the bent state, which will be described later, of the display device 1.

### Occurrence of Peeling Stress

In a case in which the display device 1 is in the bent state, peeling stress that acts in a direction in which the plurality of layers of the display panel 10 peel off from one another may occur between the plurality of layers. In particular, in the display device 1 according to the present embodiment, the peeling stress mainly occurs at the outward bending portion 17. The occurrence of the peeling stress at the outward bending portion 17 is mainly caused by an occurrence of displacement between layers of the display panel 10 at the inward bending portion 16.

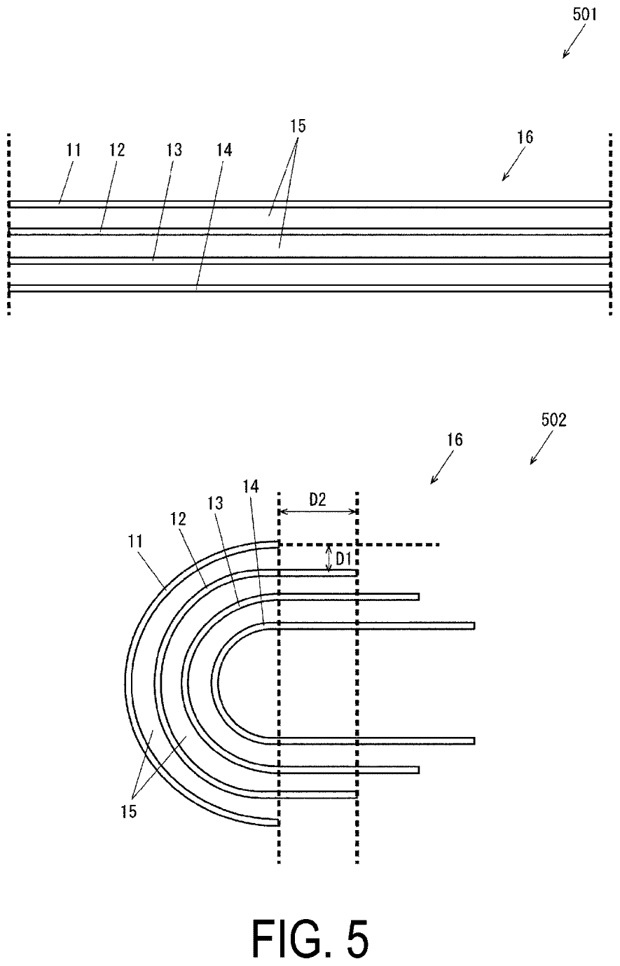

The displacement between layers of the display panel 10 at the inward bending portion 16 will be described in detail with reference to FIG. 5. FIG. 5 is a schematic view of the inward bending portion 16 of the display panel 10 in a case in which the display device 1 is in each of the extended state and the bent state. In particular, a schematic view 501 illustrates the side surface 10S at the inward bending portion 16 in a case in which the display device 1 is in the extended state, and a schematic view 502 illustrates the side surface 10S at the inward bending portion 16 in a case in which the display device 1 is in the bent state. Between each of the layers of the display panel 10 illustrated in the schematic view 501 and each of the layers of the display panel 10 illustrated in the schematic view 502, a distance from an end portion on a side of the first portion 10A to an end portion on a side of the second portion 10B is the same.

For example, as illustrated in the schematic view 501, in a case in which the display device 1 is in the extended state, the end portions of each of the layers of the inward bending portion 16 on each side of the first portion 10A and the second portion 10B substantially coincide with each other in a plan view of the display panel 10. On the other hand, as illustrated in the schematic view 502, in a case in which the display device 1 is in the bent state, the positions of the end portions of each of the layers of the inward bending portion 16 on each side of the first portion 10A and the second portion 10B differ depending on the layers of the display panel 10.

This is due to a difference in bending radius between a side of the light-emitting element layer 11 and a side of the window film 14 in the inward bending portion 16. In particular, in the present embodiment, since the inward bending portion 16 is curved with a side of the window film 14 on the inner side, a curved portion of the light-emitting element layer 11 becomes larger than a curved portion of the window film 14. For example, as illustrated in the schematic view 502, in a case in which an interlayer distance D1 between two adjacent layers in the display panel 10 is defined, a displacement distance D2 between the end portions of the two adjacent layers on one end side of the inward bending portion 16 is (π×D1)/2. For example, assuming that the interlayer distance D1 between two layers of the display panel 10 is 100 μm, the displacement distance D2 between the two layers on one end side of the inward bending portion 16 is approximately 157 μm. Note that, in the present embodiment, the interlayer distance D1 between two adjacent layers in the display panel 10 may be a distance between the midpoints of the two adjacent layers in a thickness direction.

On the other hand, at the end portion on the side of the first portion 10A and the end portion on the side of the second portion 10B of the display panel 10, the positions of the end portions of each of the layers of the display panel 10 in a plan view are substantially fixed regardless of bending and extending of the display device 1. For this reason, in a case in which the display device 1 is in the bent state, in each of the layers on the side closer to the light-emitting element layer 11 than to the window film 14 of the display panel 10, stress in a direction of extension occurs between the first portion 10A and the inward bending portion 16, and between the second portion 10B and the inward bending portion 16.

In order to relieve the stress, in each of the layers on the side closer to the light-emitting element layer 11 than to the window film 14 of the display panel 10, stress occurs that tends to cause movement toward a position where a length between the first portion 10A and the inward bending portion 16, and a length between the second portion 10B and the inward bending portion 16 become shorter. Here, the outward bending portions 17 are located between the first portion 10A and the inward bending portion 16 and between the second portion 10B and the inward bending portion 16. In the outward bending portion 17, in order for the length between the first portion 10A and the inward bending portion 16, and the length between the second portion 10B and the inward bending portion 16 to become shorter, a curvature radius at the outward bending portion 17 needs to be increased.

Therefore, in each of the layers on the side closer to the light-emitting element layer 11 than to the window film 14 of the display panel 10 at the outward bending portion 17, stress occurs in a direction of increasing the curvature radius at the outward bending portion 17, in other words, in a direction of peel from the window film 14. In a case in which the above-described stress becomes greater than a bonding force of the bonding layer 15 that bonds each of the layers of the display panel 10, peeling of each of the layers of the display panel 10 may occur at the outward bending portion 17 of the display panel 10. In addition, even in a case in which the above-described stress is smaller than the bonding force of the bonding layer 15 that bonds each of the layers of the display panel 10, the display panel 10 may be damaged by the above-described stress.

### Relief of Peeling Stress

The display device 1 according to the present embodiment includes the locking portion 30 on the outer edge of the outward bending portion 17. The first opposing portions 31 of the locking portion 30 oppose the upper surface 10T at the outward bending portion 17, and the second opposing portion 32 of the locking portion 30 opposes the lower surface 10U at the outward bending portion 17. Therefore, the locking portion 30 supports each of the layers at the outward bending portion 17 of the display panel 10 in a direction in which each of the layers is pressed against one another.

Therefore, even in a case in which the display device 1 according to the present embodiment is in the bent state and the peeling stress occurs in each of the layers at the outward bending portion 17 of the display panel 10, the locking portion 30 supports each of the layers at the outward bending portion 17 of the display panel 10 in a direction in which the peeling stress is relieved. Accordingly, the display device 1 relieves the peeling stress of each of the layers of the display panel 10 at the outward bending portion 17 and reduces the peeling of each of the layers of the display panel 10.

The bonding layer 15 according to the present embodiment includes an adhesive material having optical transparency. The adhesive material can bond each of the layers of the display panel 10 with a simple configuration while reducing an influence on light from the light-emitting element layer 11, but tends to make the problem of peeling of each of the layers of the display panel 10 due to the above-described peeling stress more prominent. Therefore, the display device 1 according to the present embodiment efficiently reduces the peeling of the display panel 10 while maintaining the effect exhibited by the bonding layer 15.

The locking portion 30 may oppose only the upper surface 10T and the lower surface 10U at the outer edges of the outward bending portions 17, among the upper surface 10T and the lower surface 10U of the display panel 10. Thus, the locking portion 30 can relieve the peeling stress of each of the layers of the display panel 10 while reducing influence on a curve at the inward bending portion 16 of the display panel 10.

In the present embodiment, the locking portion 30 is formed in each of the outward bending portions 17 between the first portion 10A and the inward bending portion 16 and between the second portion 10B and the inward bending portion 16. Thus, the locking portion 30 can reduce peeling of the display panel 10 in both the outward bending portion 17 on a side of the first portion 10A from the inward bending portion 16 and the outward bending portion 17 on a side of the second portion 10B from the inward bending portion 16.

The locking portion 30 may include stainless steel, for example. Accordingly, the locking portion 30 improves a degree of followability of deformation to the curve of the display panel 10, and reduces damage to the display panel 10. However, the material of the locking portion 30 is not limited thereto, and may include various materials having rigidity to the extent that the locking portion 30 is deformed along the curve at the outward bending portion 17 of the display panel 10.

### Method for Manufacturing Display Device

In the display device 1 according to the present embodiment, the display panel 10 may be manufactured by a known method. For example, the display panel 10 may be manufactured by sequentially performing film formation of materials of each of the layers on a base material such as a film substrate. Subsequently, the locking portion 30 may be formed on the display panel 10 by inserting the edge at the outward bending portion 17 of the manufactured display panel 10 between the first opposing portions 31 and the second opposing portion 32 of the locking portion 30 and installing the locking portion 30 on the display panel 10.

Bonding between the display panel 10 and the first housing 21 and the second housing 22 may be performed by attaching the adhesive tapes 23 to each of the upper surfaces of the first housing 21 and the second housing 22 of the housing portion 20, and then attaching the display panel 10 to the adhesive tapes 23. Subsequently, the manufacturing of the housing portion 20 may be completed and the manufacturing of the display device 1 may also be completed by covering the display panel 10, the first housing 21, and the second housing 22 with the bezel 26. Note that installation of the locking portion 30 onto the display panel 10 may be performed after bonding between the display panel 10 and the first housing 21 and the second housing 22, and formation of the bezel 26.

By the above-described method for manufacturing the display device 1, a display device 1 including the locking portion 30 that relieves the peeling stress of the display panel 10 is manufactured. Further, in the above-described method for manufacturing the display device 1, installation of the locking portion 30 onto the display panel 10 is completed by inserting the outward bending portion 17 of the display panel 10 between the first opposing portions 31 and the second opposing portion 32 of the locking portion 30. Therefore, the above-described method for manufacturing the display device 1 facilitates formation of the locking portion 30 onto the display panel 10.

### Second Embodiment

### Another Example of Display Device

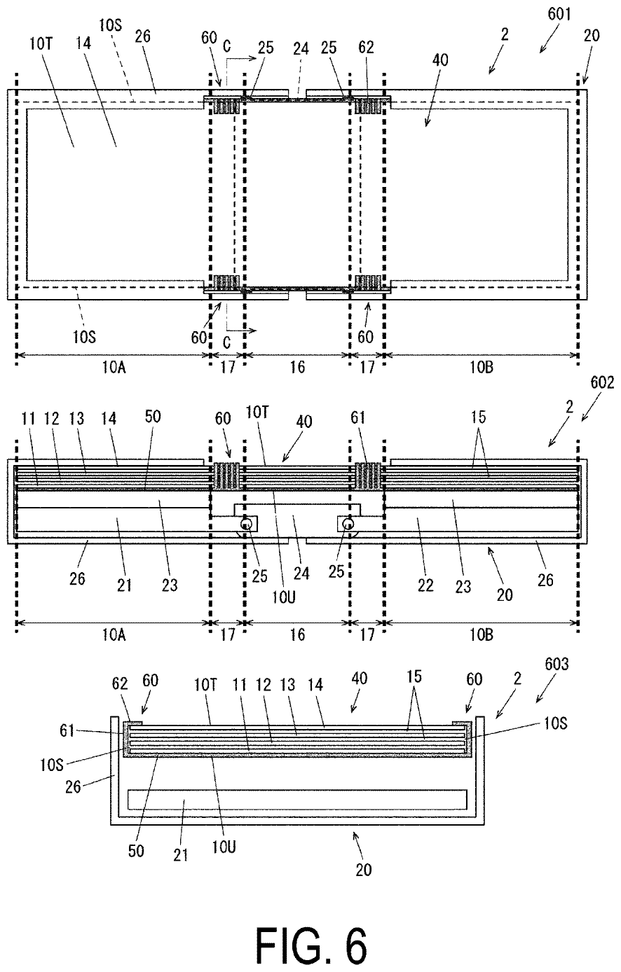

FIG. 6 is a schematic view of a display device 2 according to the present embodiment. In particular, FIG. 6 illustrates a schematic plan view 601 of the display device 2, a schematic side view 602 of the display device 2, and a schematic cross-sectional view 603 of the display device 2. In particular, the schematic plan view 601 is a plan view of the display device 2 as viewed from a side of an upper surface 10T including a display surface of a display panel 40 described later. In addition, the schematic side view 602 is a side view illustrating a side surface along a longitudinal direction of the display device 2. Further, the schematic cross-sectional view 603 is a cross-sectional view taken along line C-C of the schematic plan view 601, in other words, a cross-sectional view in a cross section orthogonal to the upper surface 10T of the display panel 40 and passing through a protrusion 60 to be described later. Note that in the schematic side view 602, a portion of a bezel 26 which is located on the near side toward the paper surface is omitted in the illustration, in order to illustrate components of the display device 2 more clearly. FIG. 6 illustrates a case in which the display device 2 is in the extended state. The case in which the display device 2 is in the extended state is a state in which the display surface of the display panel 40, which will be described later, is located substantially on the same plane.

The display device 2 according to the present embodiment includes the display panel 40 in place of the display panel 10, as compared with the display device 1 according to the previous embodiment. The display panel 40 according to the present embodiment includes, for example, a mesh layer 50, which is bonded to a light-emitting element layer 11 via a bonding layer 15, on a side closer to a first housing 21 and a second housing 22 than to the light-emitting element layer 11, as compared with the display panel 10 according to the previous embodiment. In other words, the display panel 40 includes the mesh layer as a lowermost layer among the plurality of layers. Therefore, the display panel 40 includes an upper surface of a window film 14 as the upper surface 10T, and a lower surface of the mesh layer 50 as a lower surface 10U. In addition, the display panel 40 includes side surfaces from the mesh layer 50 to the window film 14 as a side surface 10S. Furthermore, the display device 2 includes, as a part of a locking portion, the protrusion 60 that is continuous with the mesh layer 50 and protrudes from an outer edge of the mesh layer 50, instead of the locking portion 30.

### Mesh Layer

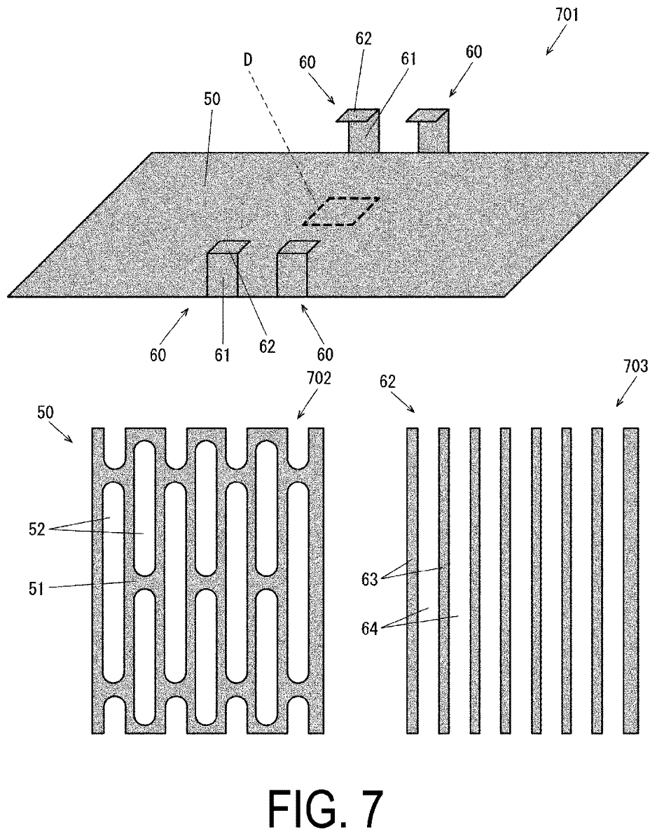

The mesh layer 50 and the protrusion 60 will be described with further reference to FIG. 7. FIG. 7 is a schematic view illustrating the mesh layer 50 and the protrusion 60 according to the present embodiment. In particular, FIG. 7 illustrates a schematic perspective view 701 of the mesh layer 50 and the protrusion 60, a schematic enlarged view 702 of the mesh layer 50, and a schematic enlarged view 703 of a top plate portion 62 of the protrusion 60, which will be described later. In particular, the schematic enlarged view 702 is a diagram illustrating an enlarged view of a region D illustrated in the schematic perspective view 701.

The mesh layer 50 is a metal thin film having a mesh pattern with a plurality of openings 52 in a thin plate portion 51 having predetermined rigidity. The thin plate portion 51 smoothly curves in accordance with an applied external force due to the formation of the plurality of openings 52. Accordingly, the mesh layer 50 has flexibility as a whole, while the thin plate portion 51 has predetermined rigidity. In a case in which the display device 2 is in the extended state, the mesh layer 50 may have a substantially flat plate shape. The thickness of the mesh layer 50 may be 50 μm. The total thickness of the display panel 40 according to the present embodiment may be, for example, from 400 μm to 600 μm.

### Protrusion

The protrusion 60 includes a side portion 61 protruding upward from the mesh layer 50, in other words, toward the window film 14, and the top plate portion 62 protruding from an upper portion of the side portion 61, in other words, from an end edge on the side of the window film 14 toward a central side of the mesh layer 50.

The side portion 61 and the top plate portion 62 are continuous with the mesh layer 50. The side portion 61 may be located on a plane substantially parallel to a longitudinal direction and a normal direction of an upper surface of the mesh layer 50, and the top plate portion 62 may be located on a plane substantially parallel to the upper surface of the mesh layer 50.

As illustrated in the schematic enlarged view 703, the top plate portion 62 includes, for example, the same material as the thin plate portion 51 of the mesh layer 50, and includes a plurality of band portions 63 extending from an outer edge of the display panel 40 along a central side thereof. Gaps 64 are formed between band portions 63 that are adjacent to each other, the gaps 64 having widths substantially equal to widths of the openings 52 of the mesh layer 50. The side portion 61 may have the same configuration as the top plate portion 62 except that the extending direction of the band portions 63 is a thickness direction of the display panel 40. The side portion 61 and the top plate portion 62 may be formed by a part of the thin plate portion 51 of the mesh layer 50 being extended to the side surface 10S and the upper surface 10T of the display panel 40.

The protrusion 60 may be formed on each of the longitudinal end edges of the mesh layer 50, and a plurality of protrusions 60 may be formed on each of the end edges.

The display panel 40 is bonded to the first housing 21 and the second housing 22 via the adhesive tapes 23. The display panel 40 includes a first portion 10A overlapping a bonding position with the first housing 21 and a second portion 10B overlapping a bonding position with the second housing 22 in a plan view, similarly to the display panel 10 according to the previous embodiment.

Further, the display panel 40 includes, between the first portion 10A and the second portion 10B, an inward bending portion 16 allowing the upper surface 10T to be curved inward and an outward bending portion 17 allowing the upper surface 10T to be curved outward. In particular, the outward bending portions 17 are located between the first portion 10A and the inward bending portion 16 and between the second portion 10B and the inward bending portion 16, respectively.

The protrusion 60 according to the present embodiment is located at an outer edge of the outward bending portion 17. In particular, the side portion 61 opposes the side surface 10S at the outward bending portion 17, and the top plate portion 62 opposes the upper surface 10T at the outward bending portion 17.

The thickness of the side portion 61 and the top plate portion 62 may be substantially the same as that of the mesh layer 50. The length of the side portion 61 in the longitudinal direction of the display device 2 may be, for example, from 5 mm to 10 mm. The length of the top plate portion 62 in the short-hand direction of the display device 2 may be, for example, from 1 mm to 2 mm. The length of the side portion 61 in the thickness direction of the display device 2, in other words, a distance between the mesh layer 50 and the top plate portion 62 may be substantially equal to the overall thickness of the display panel 40, for example.

### Curving of Mesh Layer and Protrusion

Except for the above, the display device 2 according to the present embodiment includes the same configuration as the display device 1 according to the previous embodiment. Therefore, the display device 2 comes into the bent state from the extended state by the first housing 21 and the second housing 22 rotating around the respective pins 25 until the upper surfaces of the first housing 21 and the second housing 22 face each other.

In a case in which the display device 2 is in the bent state, the display panel 40 curves between the first portion 10A and the second portion 10B. Here, the display panel 40 of the display device 2 in the bent state curves with the upper surface 10T inward at the inward bending portion 16, and curves with the upper surface 10T outward at the outward bending portion 17.

Therefore, the display panel 40 curves in a teardrop shape between the first portion 10A and the second portion 10B.

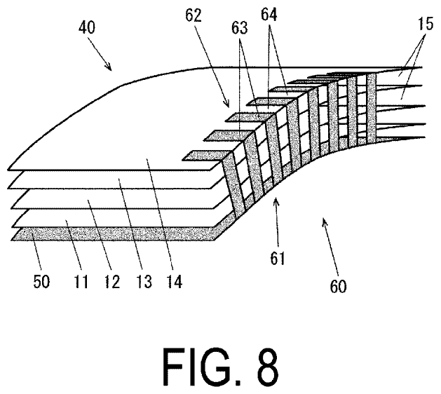

The mesh layer 50 and the protrusion 60 in a case in which the display device 2 is in the bent state will be described with reference to FIG. 8. FIG. 8 is a schematic enlarged view illustrating the protrusion 60 and the display panel 40 located in the vicinity of the protrusion 60 in a case in which the display device 2 is in the bent state.

Since the mesh layer 50 has flexibility as described above, the mesh layer 50 curves along the curve of the light-emitting element layer 11 at the outward bending portion 17. Further, the side portion 61 and the top plate portion 62 of the protrusion 60 deform so as to widen the intervals of the gaps 64 between the plurality of band portions 63, along with curving of the mesh layer 50.

Accordingly, the mesh layer 50 and the protrusion 60 deform in accordance with a curve of the outward bending portion 17. In particular, the side portion 61 and the top plate portion 62 of the protrusion 60 improve a degree of followability with respect to a curve of the display panel 40, as compared with the locking portion 30 including the first opposing portions 31 and the connection portions 33, and reduce damage to the display panel 40.

The mesh layer 50 and the protrusion 60 may include, for example, stainless steel. As a result, the mesh layer 50 and the protrusion 60 improve a degree of followability of deformation with respect to the curve of the display panel 40 and reduce damage to the display panel 40.

### Relief of Peeling Stress by Protrusion

For the same reason as described in the previous embodiment, in a case in which the display device 2 is in the bent state, peeling stress occurs in the outward bending portion 17 in each of the layers on a side of the light-emitting element layer 11 rather than the mesh layer 50 of the display panel 40. Here, the top plate portion 62 of the protrusion 60 according to the present embodiment opposes the upper surface 10T at the outward bending portion 17. Therefore, the top plate portion 62 and a portion of the mesh layer 50 overlapping the top plate portion 62 in a plan view of the display panel 40 support, at the outer edge of the outward bending portion 17, each of the layers from the light-emitting element layer 11 to the window film 14 of the display panel 40 in a direction to press each of the layers against one another.

Therefore, the display device 2 relieves peeling stress in each of the layers of the display panel 40 at the outward bending portion 17 and reduces peeling of each of the layers of the display panel 40. Therefore, a portion of the mesh layer 50 overlapping the top plate portion 62 in the plan view of the display panel 40 functions as a part of the locking portion that supports the outward bending portion 17 together with the protrusion 60.

### Modified Example of Method for Manufacturing Display Device

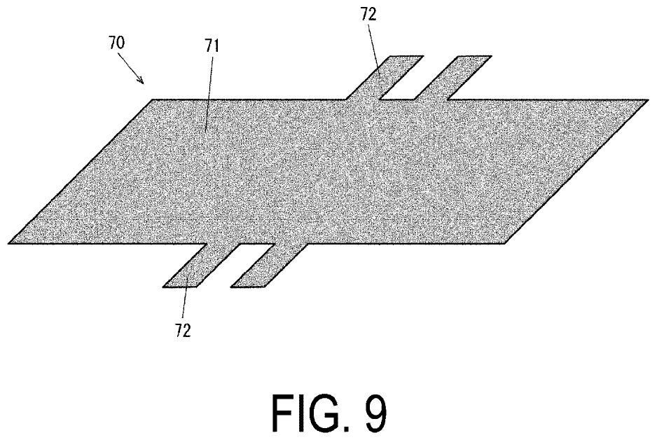

When compared with a method for manufacturing the display device 1 according to the previous embodiment, a method for manufacturing the display device 2 according to the present embodiment may be performed by the same method, except that a forming process of the display panel 40 is included instead of a forming process of the display panel 10. The forming process of the display panel 40 according to the present embodiment will be described with reference to FIG. 9. FIG. 9 is a schematic perspective view of a mesh material layer 70, which will be described later, formed in the forming process of the display panel 40 according to the present embodiment.

In the forming process of the display panel 40 according to the present embodiment, first, the mesh material layer 70 illustrated in FIG. 9 is formed. The mesh material layer 70 includes a mesh layer portion 71 that overlaps, in a plan view, the light-emitting element layer 11 to be formed in a subsequent process, and a protrusion 72 that protrudes from an outer edge of the mesh layer portion 71 and is located substantially on the same plane as the mesh layer portion 71.

The mesh layer portion 71 may have, for example, the same structure as the mesh layer 50 and may be formed, for example, by performing film formation of a thin plate portion 51 by sputtering or the like, and then forming the plurality of openings 52 in the thin plate portion 51 by etching. The protrusion 72 is formed at a position adjacent to the outward bending portion 17 of the display panel 40 after the formation of the display panel 40 is completed. The protrusion 72 may include the plurality of band portions 63 extending in a direction from the center of the mesh layer portion 71 toward the outer edge, with the gaps 64 provided therebetween. The protrusion 72 may be formed in the same forming process as a forming process of the mesh layer portion 71.

After the mesh material layer 70 is formed, each of the layers from the light-emitting element layer 11 to the window film 14 may be formed by sequentially performing film formation of materials of each of the layers on the mesh material layer 70. The layers from the light-emitting element layer 11 to the window film 14 may be formed at a position overlapping the mesh layer portion 71 in a plan view of the mesh material layer 70. As a result, the mesh layer portion 71 of the mesh material layer 70 becomes the mesh layer 50, and the forming process of the display panel 40 is completed. At the time of completion of the forming process of the display panel 40, the protrusion 72 of the mesh material layer 70 protrudes from the outer edge of the outward bending portion 17 of the display panel 40 in a plan view of the display panel 40.

Subsequently, the protrusion 72 is bent toward the side surface 10S at the outward bending portion 17 of the display panel 40. Thus, a part of the protrusion 72 becomes the side portion 61 opposing the side surface 10S at the outward bending portion 17 of the display panel 40. In addition, another part of the protrusion 72 protrudes further upward from the upper surface 10T at the outward bending portion 17 of the display panel 40.

Subsequently, a part of the protrusion 72 protruding upward from the upper surface 10T at the outward bending portion 17 is bent toward a central side of the upper surface 10T at the outward bending portion 17. As a result, a part of the protrusion 72 becomes the top plate portion 62 opposing the upper surface 10T at the outward bending portion 17, and a forming process of the protrusion 60 is completed.

Note that, in the method for manufacturing the display device 2 according to the present embodiment, the attachment of the display panel 40 to the first housing 21 and the second housing 22, and the formation of the bezel 26 are performed after the formation of the display panel 40. In the present embodiment, the attachment and the formation of the bezel 26 may be performed before or after the protrusion 60.

By the above-described method for manufacturing the display device 2, the display device 2 including the mesh layer 50 and the protrusion 60 that relieve the peeling stress of the display panel 40 is manufactured. In particular, the display device 2 according to the present embodiment includes the mesh layer 50, which is the lowermost layer of the display panel 40, and the protrusion 60, which is continuous with the mesh layer 50. Therefore, the protrusion 60 of the display device 2 can be simply formed by the process of bending the above-described protrusion 72. Note that the mesh layer 50 may be located at the uppermost layer of the display panel 40, and in this case, the protrusion 60 may be formed by bending the protrusion 72 toward the lower surface 10U of the display panel 40. In this case, the top plate portion 62 may oppose the lower surface 10U.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A display device comprising:
a display panel layered with a plurality of layers having flexibility; and
at least one locking portion located at a part of an outer edge of the display panel,
wherein the display panel includes an upper surface and a lower surface, the display panel further including an inward bending portion allowing the upper surface to be curved inward and an outward bending portion allowing the upper surface to be curved outward, the locking portion including a first opposing portion opposing the upper surface at the-an outer edge of the outward bending portion, a second opposing portion opposing the lower surface at the outer edge of the outward bending portion, and a connection portion connecting the first opposing portion and the second opposing portion.

2. The display device according to claim 1,
wherein the locking portion opposes only the upper surface and the lower surface at the respective outer edges of the outward bending portion among the upper surface and the lower surface of the display panel.

3. The display device according to claim 1,
wherein the locking portion includes a plurality of the first opposing portions, a plurality of the connection portions, and the single second opposing portion.

4. The display device according to claim 3,
wherein the second opposing portion curves in accordance with a curve of the display panel.

5. The display device according to claim 1,
wherein the locking portion is continuous with either a lowermost layer or an uppermost layer among the plurality of layers of the display panel.

6. The display device according to claim 5,
wherein the display panel includes a mesh layer including a metal thin film including a mesh pattern, and the locking portion is continuous with the mesh layer.

7. The display device according to claim 6,
wherein the locking portion includes a protrusion protruding from an outer edge of the mesh layer and opposing a side surface of the display panel and either the upper surface or the lower surface of the display panel.

8. The display device according to claim 1,
wherein the locking portion includes stainless steel.

9. A display device according to claim 1, comprising:
a first housing bonded to a lower surface of the display panel; and
a second housing different from the first housing,
wherein the display panel includes a first portion overlapping, in a plan view, a bonding position between the first housing and the display panel, a second portion overlapping, in a plan view, a bonding position between the second housing and the display panel, the inward bending portion being located between the first portion and the second portion, and the outward bending portions being located at each position between the first portion and the inward bending portion, and between the second portion and the inward bending portion.

10. The display device according to claim 9, comprising:
a hinge portion rotatably connecting the first housing and the second housing to each other,
wherein the locking portion is located in a periphery of the hinge portion in a side view.

11. The display device according to claim 9, comprising:
a lower surface and a side surface of the first housing and a lower surface and a side surface of the second housing, an outer edge and a side surface of the upper surface of the display panel, and a bezel covering a periphery of the locking portion.

12. The display device according to claim 1,
wherein the display panel includes at least one bonding layer bonding the plurality of layers, the bonding layer including an adhesive material having optical transparency.

13. A method for manufacturing a display device including a display panel including a plurality of layers having flexibility, the display panel including an upper surface and a lower surface, the display panel further including an inward bending portion allowing the upper surface to be curved inward and an outward bending portion allowing the upper surface to be curved outward, the method comprising:
forming the display panel by layering the plurality of layers; and
forming a locking portion including a first opposing portion opposing the upper surface at an outer edge of the outward bending portion, a second opposing portion opposing the lower surface at the outer edge of the outward bending portion, and a connection portion connecting the first opposing portion and the second opposing portion.

14. The method for manufacturing the display device according to claim 13,
wherein the forming the locking portion includes installing the locking portion on the display panel by inserting an edge of the display panel between the first opposing portion and the second opposing portion.

15. The method for manufacturing the display device according to claim 13,
wherein the forming the locking portion includes bending, toward a side surface and either an upper surface or a lower surface of the display panel, a protrusion continuous with either a lowermost layer or an uppermost layer among the plurality of layers of the display panel and protruding from the display panel in a plan view.
